(19) United States
(12) Patent Application Publication
(10) Pub. No.: US 2007/0217119 A1
(43) Pub. Date: Sep. 20, 2007

(54) Apparatus and Method for Carrying Substrates

(76) Inventors: David Johnson, Palm Harbor, FL (US); Shouliang Lai, Tampa, FL (US)

Correspondence Address: HARVEY S. KAUGET;PHELPS DUNBAR, LLP, 100 S. ASHLEY DRIVE, SUITE 1900, TAMPA, FL, 33602-5311, US

(21) Appl. No.: 11/681,805

(22) Filed: Mar. 5, 2007

Related U.S. Application Data
(60) Provisional application No. 60/783,614, filed on Mar. 17, 2006.

(51) Int. Cl. B23B 31/28; H01L 21/683; H01L 21/306; C23C 16/00

(52) U.S. Cl. 361/234; 279/128; 118/728; 156/345.51

(57) ABSTRACT

The present invention provides a method and an apparatus for carrying at least one substrate for plasma processing. The method and apparatus comprising a carrier for transporting the substrate, that is located unbonded on the carrier, onto a substrate support within a plasma system for plasma processing. An electrostatic clamp, that is coupled to the substrate support, electrostatically secures the substrate to the substrate support through the carrier during plasma processing.

### CROSS REFERENCES TO RELATED APPLICATIONS

This application claims priority from and is related to commonly owned U.S. Provisional Patent Application Ser. No. 60/783,614 filed Mar. 17, 2006, entitled: Apparatus and Method for Carrying Substrates, this Provisional Patent Application incorporated by reference herein.

### FIELD OF THE INVENTION

The present invention generally relates to semiconductor processing, and more specifically to the handling of wafers during etch and deposition processes.

### BACKGROUND

Plasma processing is widely used in the manufacture of both semiconductor and non semiconductor devices which may utilize silicon and other semiconductor substrates (such as GaAs) or materials such as quartz, sapphire or various metallic materials. The processing may involve deposition of different materials or removal of materials (etching) from the substrate. A photo-resist mask is often used to protect areas of the substrate from etching, so that a pattern may be transferred to the substrate surface.

Exposure to the plasma during processing exposes the substrate to a source of energy in the form of bombardment by ions and electrons. This energy results in beat being deposited into the substrate, which, if not removed effectively, will cause a rise in temperature of the substrate. In some processes this may be used to advantage, but more often an excessive temperature rise produces undesirable side effects such as photo-resist degradation or poor device performance. The generation of heat is more problematic when high density plasma sources, such as inductively coupled plasma (ICP), are used.

A number of techniques are used to remove heat from the substrate in order to control the temperature during processing. The most commonly used technique is to introduce a gas between the substrate and a temperature controlled substrate support in order to provide a conductive pathway for heat removal. Helium is frequently chosen since it is inert and has (among gases) a high thermal conductivity. In order to be effective, helium must be present at a pressure of at least a few Torr, and since most plasma processes operate at a pressure lower than this, a means of sealing the helium behind the substrate is necessary. This is achieved by holding the substrate in close contact to the support using a clamp arrangement. A mechanical clamp which presses on the front side of the wafer can be used. However, a mechanical clamp may cause problems since contact with the front side of the substrate may damage devices or cause particle generation.

An alternative clamping arrangement, which is frequently used, employs an Electrostatic Chuck (ESC). The substrate is clamped to the support by means of electrostatic attraction from one or more insulated electrodes embedded within the substrate support and to which a high voltage can be applied (FIG. 1). For the electrostatic clamping to be effective, the substrate must be electrically conducting (e.g., aluminum) or partially conducting (e.g., silicon, silicon carbide etc). Insulating substrates, such as sapphire or quartz, do not clamp efficiently. The use of an ESC is widely accepted and is used in the production of devices fabricated on up to 300 nm diameter silicon wafers.

It is well known that the use of an ESC can result in some charge remaining on the substrate after the clamping process. Any residual charge will result in an attractive force between the substrate and the support. If the residual charge is large enough, the substrate cannot be removed easily from the support which causes problems with the substrate handling mechanism which, in a worse case scenario, can result in a broken or damaged substrate. Many techniques have been described in the literature and used to reduce the problem of damage and or breakage (such as ESC polarity reversal, various ESC voltage waveforms or mechanical assists). Even though residual charge is not completely eliminated it can be reduced to a low enough value that handling problems are not encountered when processing standard silicon wafers.

Recently there has been a large effort to improve the design and manufacture of Micro Electro Mechanical Systems (MEMS) devices. The design and manufacture of MEMS are differentiated from the more standard silicon devices in that frequently very deep etches into a silicon substrate are performed. The silicon substrates used in the design and manufacture of MEMS are often thinner than “standard” substrates and it is not uncommon to etch completely through the wafer, leaving sections of silicon attached via thin beams or thin membranes. The net result is that after processing, the wafer is extremely fragile. When such fragile wafers are processed using an ESC, any residual charge will cause severe handling problems which will inevitably result in broken wafers. This causes loss of productivity due to the necessary time required for system recovery from the maintenance necessary to remedy the broken wafers within the plasma processing system. Problems associated with residual charge are aggravated when the wafer is coated with a dielectric film (e.g., silicon dioxide) since it is difficult for any accumulated charge to neutralize through a nonconductive material. Such nonconductive structures are frequently encountered in the design and manufacture of MEMS devices.

Placing the substrate on a carrier for transfer and processing can prevent breakage issues, but this does not address the heat removal issue. Bonding the substrate to the carrier using a thermally conductive paste or adhesive and also clamping the carrier either mechanically or by ESC to the temperature controlled support member can provide the necessary temperature control (see Weichart, U.S. Patent Application Number 2006/0108231). However, such a procedure with the necessary de-bonding procedure as described in Weichart is time consuming, potentially contaminating and is likely to increase the chance of damage to thin or fragile substrates due to the additional handling requirements.

Thus, what is needed is a means of handling fragile substrates that is compatible with techniques that provide the necessary cooling to permit plasma processing.

Nothing in the prior art provides the benefits attendant with the present invention.

Therefore, it is an object of the present invention to provide an improvement which overcomes the inadequacies of the prior art devices and which is a significant contribution to the advancement of the semiconductor processing art.

Another object of the present invention is to provide an apparatus for carrying at least one substrate for plasma processing, comprising a substrate support; a carrier for transporting the substrate onto said substrate support, wherein the substrate is located unbonded on said carrier; and a clamping mechanism coupled to said substrate support, wherein said clamping mechanism is configured to move between an inactive position and an active position, whereby the substrate is clamped to said substrate support through said carrier when said clamping mechanism is in said active position.

Yet another object of the present invention is to provide an apparatus for carrying at least one substrate for plasma processing, comprising a substrate support; a carrier for transporting the substrate onto said substrate support, wherein the substrate is located unbonded on said carrier; and an electrostatic clamp coupled to said substrate support, wherein the substrate is electrostatically secured to said substrate support through said carrier by said electrostatic clamp.

Still yet another object of the present invention is to provide a method for carrying at least one substrate for plasma processing, comprising providing a substrate support; providing an electrostatic clamp coupled to said substrate support; providing a carrier; placing the substrate onto said carrier, the substrate is located unbonded on said carrier; transporting the carrier with the unbonded substrate onto said substrate support; and electrostatically clamping the substrate to said substrate support through said carrier by said electrostatic clamp.

The foregoing has outlined some of the pertinent objects of the present invention. These objects should be construed to be merely illustrative of some of the more prominent features and applications of the intended invention. Many other beneficial results can be attained by applying the disclosed invention in a different manner or modifying the invention within the scope of the disclosure. Accordingly, other objects and a fuller understanding of the invention may be had by referring to the summary of the invention and the detailed description of the preferred embodiment in addition to the scope of the invention defined by the claims taken in conjunction with the accompanying drawings.

### SUMMARY OF THE INVENTION

For the purpose of summarizing this invention, the present invention provides a carrier which is designed to carry at least one substrate and which can be placed on an ESC. The carrier is fabricated of a material which allows the substrate(s) to be electrostatically clamped through the carrier, permitting the use of helium gas behind the substrate(s) which provides cooling of the substrate(s) during plasma processing.

A feature of the present invention is to provide an apparatus for carrying at least one substrate for plasma processing. The apparatus comprising a carrier for transporting the substrate onto a substrate support within a plasma processing system. The substrate is located unbonded on the carrier. The positioning of the unbonded substrate on the carrier can be a maintained by a plurality of retaining pins or an optional cover plate that creates a recess for the substrate. The cover plate can be integral to the carrier or be a separate part. The cover plate is designed to be resistant to the plasma that will be used to process the substrate. A mechanical or electrostatic clamp is coupled to the substrate support. The clamping mechanism is configured to move between an inactive position and an active position, whereby the substrate is clamped to the substrate support through the carrier when the clamping mechanism is in the active position. The carrier can be designed with a plurality of holes that allow for the conduction of a gas, such as helium, for cooling the backside of the substrate during plasma processing.

Another feature of the present invention is to provide an apparatus for carrying at least one substrate for plasma processing. The apparatus comprising a carrier for transporting the substrate onto a substrate support within a plasma processing system. The substrate is located unbonded on the carrier. The positioning of the unbonded substrate on the carrier can be maintained by a plurality of retaining pins or an optional cover plate that creates a recess for the substrate. The cover plate can be integral to the carrier or be a separate part. The cover plate is designed to be resistant to the plasma that will be used to process the substrate. An electrostatic clamp is coupled to the substrate support which electrostatically clamps the substrate to the substrate support through the carrier when the electrostatic clamp is activated. In addition, the carrier can be made of a dielectric material (such as alumina, aluminum oxide ceramic, sapphire or quartz) to effectively interact with the electrostatic force from the electrostatic clamp. The carrier can be designed with a plurality of holes that allow for the conduction of a gas, such as helium, for cooling the backside of the substrate during plasma processing.

Yet another feature of the present invention is to provide a method for carrying at least one substrate for plasma processing. The method comprising providing a substrate support; providing an electrostatic clamp coupled to the substrate support; and providing a carrier. The substrate can be a MEMS substrate and the substrate can have a dielectric film such as silicon dioxide. The substrate is placed onto the carrier and is located unbonded on the carrier. The positioning of the unbonded substrate on the carrier can be maintained by a plurality of retaining pins or an optional cover plate that creates a recess for the substrate. The cover plate can be integral to the carrier or be a separate part. The cover plate is designed to be resistant to the plasma that will be used to process the substrate. The carrier with the unbonded substrate is transported onto the substrate support. The electrostatic clamp is then activated to electrostatically clamp the substrate to the substrate support through the carrier. In addition, the carrier can be made of a dielectric material (such as alumina, aluminum oxide ceramic, sapphire or quartz) to effectively interact with the electrostatic force from the electrostatic clamp. The carrier can be designed with a plurality of holes that allow for the conduction of a gas, such as helium, for cooling the backside of the substrate during plasma processing. In additions the substrate can made of an electrically conducting (such as aluminum) or partially conducting (such as silicon or silicon carbide) material to allow for the effective electrostatic clamping of the substrate through the carrier when the electrostatic clamp is activated.

The foregoing has outlined rather broadly the more pertinent and important features of the present invention in order that the detailed description of the invention that follows may be better understood so that the present contribution to the art can be more fully appreciated. Additional features of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

FIG. 1 is a schematic of a typical Electrostatic Chuck of the prior art;

FIG. 2 is a schematic of an Eletrostatic Chuck with a substrate carrier of the present invention;

FIG. 3 is a schematic of one embodiment of the substrate carrier of the present invention having a plurality of holes for the flow of helium and a plurality of substrate retaining pins for holding a single substrate;

FIG. 4 is a graph of temperature versus time showing the improved cooling efficiency of the present invention;

FIG. 5 is a schematic of another embodiment of the substrate carrier of the present invention being able to carry a plurality of substrates and having a plurality of holes for the flow of helium to each substrate on the carrier; and

FIG. 6 is a schematic of another embodiment of the substrate carrier of the present invention showing a cover plate.

Similar reference characters refer to similar parts throughout the several views of the drawings.

### DETAILED DESCRIPTION OF THE INVENTION

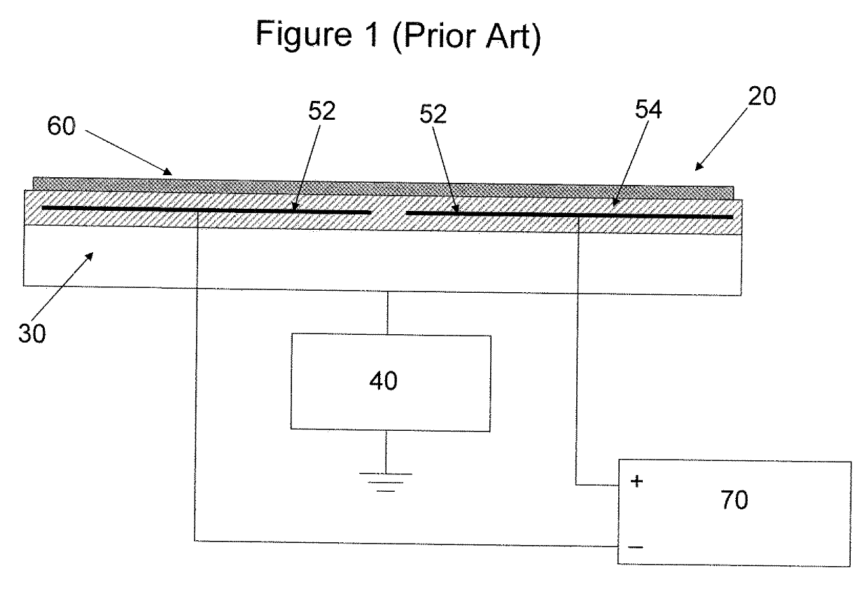

FIG. 1 depicts the fabrication of a typical Electrostatic Chuck as known in the prior art. As shown, a typical Electrostatic Chuck 20 comprises a substrate support electrode 30 which is typically RF powered 40, though a grounded substrate support may also be used, and on which is built the electrostatic component 50. The electrostatic component 50 consists of one or more electrodes 52 which are isolated from the support member 30 by a dielectric material 54 and is also isolated from the substrate 60 by the same or a different dielectric material 54. A power supply 70 applies a voltage to the electrodes 52. The voltage is usually a dc voltage, but it may be cycled, polarity reversed or pulsed in various manners as is well known in the art. The applied voltage generates an electrostatic attractive force to the substrate 60.

The magnitude of this force is given by the formula:

F=eₒ/2*(V*e/(d+e*g))²

Where:

F=generated electrostatic force (in Pascals)

eₒ=permittivity of free space (8.85×10⁻¹²)

V=voltage difference between substrate and electrode

e=dielectric constant of dielectric layer

d=thickness of dielectric layer

g=gap between substrate and surface of ESC

A commonly used dielectric material is aluminum oxide (either in the form of a ceramic or as sapphire) which has a dielectric constant, e, of approximately 10. The dielectric thickness is of the order of fractions of a millimeter (10⁻⁴-10⁻³ m) and the gap between the substrate and the ESC surface can be reduced to a few microns of few tens of microns (10⁻⁶-10⁻⁵ m). A voltage of 1000 V is commonly used. Parameters in these ranges will result in clamping forces in the range of kPa to 10's of kPa which permits a helium pressure in the range of Torr to few 10's of Torr to be contained behind the substrate.

To maximize the clamping force felt by the substrate, the carrier should be as thin as possible. In the above equation the clamping force is inversely proportional to d². When a carrier is used, assuming the ESC and carrier dielectrics are similar (similar values of e), then d represents the total thickness of dielectric between the substrate and the ESC electrode which is the sum of the ESC dielectric and the carrier thickness. Since the ESC dielectric thickness is fixed, the clamping force is maximized if the carrier thickness is minimized. The limiting factor is the mechanical stability of the carrier. The carrier must be sufficiently rigid so that it does not bend, bow or break during handling; otherwise, all advantages of using a carrier are lost. The thickness of the carrier depends on the size of the substrate handled. For example, we have found that a suitable carrier for a 150 mm diameter silicon wafer can be made from alumina ceramic which is 0.25-0.5 mm in thickness. A similar thickness of sapphire is also suitable. Whereas, carriers for larger substrates (200 mm or 300 mm diameter wafers) need to be somewhat thicker, but for smaller substrates an even thinner material is suitable. For very thin carrier materials, it is also possible to construct the carrier with a thinner central section on which the substrate is located, and a thicker peripheral area which serves to add mechanical strength. In the limiting case, the inner area may be a thin membrane.

Although not part of the present invention, the ESC can be modified to work optimally with a carrier. The upper dielectric layer can be thinned, or even omitted entirely, to reduce the overall dielectric thickness. Normally, this is undesirable since a thin dielectric layer is prone to electrical breakdown between the ESC electrode and the wafer; however, in this instance the thickness of the carrier dielectric will prevent such breakdown problems.

The diameter of the carrier should be larger than the substrate, but can be such that it can still be easily handled by typical wafer handling robots. For example, a carrier designed to handle a 150 mm diameter wafer can be made with a diameter of 154 mm, Such a carrier is easily handled without major changes to the handling mechanism. In fact, an added advantage of such an approach is that the same mechanism and the same plasma system may be used to process both carried and un-carried wafers without changes.

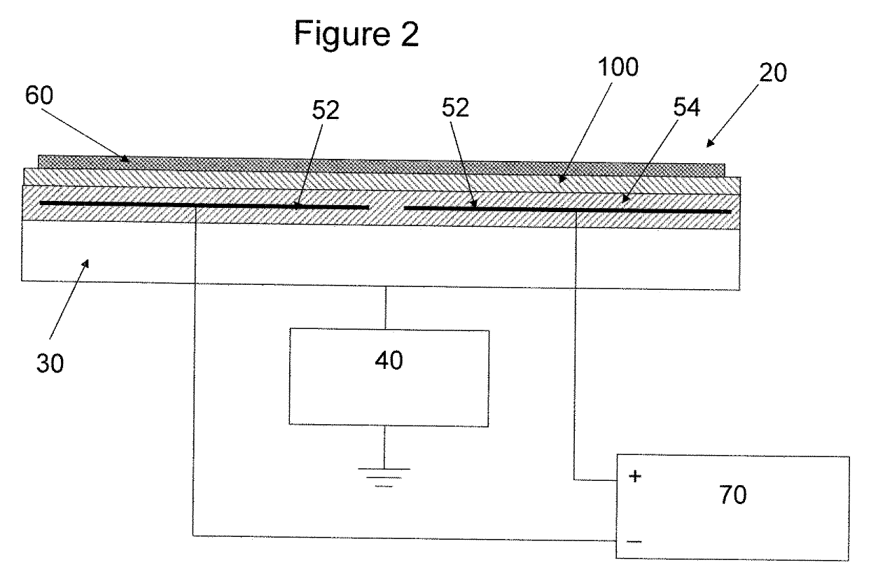

As shown in FIG. 2, the present invention uses a carrier 100 to transport the substrate 60 onto the support electrode 30 for plasma processing on an electrostatic chuck 20. The substrate 60 is placed unbonded onto the carrier 100 prior to plasma processing. Next, the carrier 100 plus the unbonded substrate 60 are transported into the plasma processing system (not shown), typically using a robotic transfer mechanism (not shown). After plasma processing, the carrier 100 plus the unbonded substrate 60 are removed from the plasma processing system and the substrate 60 is removed from the carrier 100.

The carrier 100 is made from a material which allows an electrostatic clamping force to be felt by the substrate 60. Thus, the carrier 100 material should be a dielectric material with similar properties to the dielectric material used in the construction of the electrostatic chuck 20. Materials such as alumina, aluminum oxide ceramic, sapphire and quartz are suitable for the dielectric material, but the choice is not limited to such materials. Conductive materials, such as aluminum, are not suitable for the carrier material.

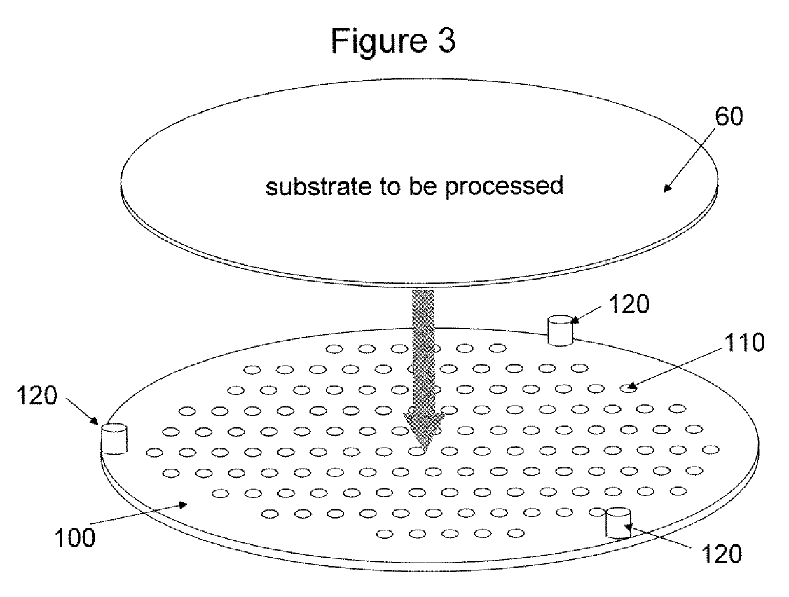

In order to provide cooling of the substrate 60 during processing, it is preferable that a pressure of helium should be maintained between the substrate 60 and the carrier 100. Helium is normally introduced to the space behind the substrate 60 through holes in the substrate electrode (not shown in FIGS. 1 and 2). An example of a carrier 100 with a plurality of holes 110 for the conduction of helium is shown in FIG. 3. Thus, in order for helium to effectively communicate to the substrate/carrier 100 interface, a number of holes 110 are made in the carrier 100. The size and distribution of these holes 110 is not critical, but, for example, a series of 1 mm diameter holes 110 spaced apart by 10 mm and extending to within 10 mm of the edge of the substrate 60, is adequate. Whereas, coating the bottom of the carrier 100 (the side in contact with the electrostatic chuck 20) with a thin layer of conductive material at the outer edge (e.g., outer 6 mm) can locally increase the clamping force of the substrate to the carrier 100 and thereby improve the helium sealing capability.

In addition, as shown in FIG. 3, in order to prevent the substrate 60 from moving when it is placed on the carrier 100, a plurality of retention pins 120 can be provided around the carrier 100 periphery. These may be discreet pins 120 or may be such that a continuous band is formed (the substrate 60 sits within a recess). The above example of a thin membrane supported by a peripheral ring would also serve as a wafer retention means.

The use of a carrier reduces the cooling efficiency compared to clamping a wafer directly on an ESC. The reduction in cooling efficiency is due to the increased total dielectric thickness which results in the clamping force being reduced. In the case when the carrier thickness is equal to the ESC dielectric thickness, the total thickness is doubled and hence the clamping force is reduced by a factor of four. Also, heat flow must occur across two helium interfaces (substrate/carrier interface and carrier/ESC interface). Since the helium interface represents the largest thermal break, the overall cooling efficiency is reduced by a factor of two. Despite these limitations, the cooling efficiency is significantly better than processing a substrate using no carrier and no clamping or processing a substrate using a carrier which does not allow the substrate to be electrostatically clamped (e.g., using a carrier made from aluminum, another conductive material or a partially conductive material will not allow an electrostatic clamping force to be felt by the substrate). The increased cooling efficiency permits higher power processes to be used which generally provides processes with higher etch (or deposition) rates, and hence, improved throughput and productivity.

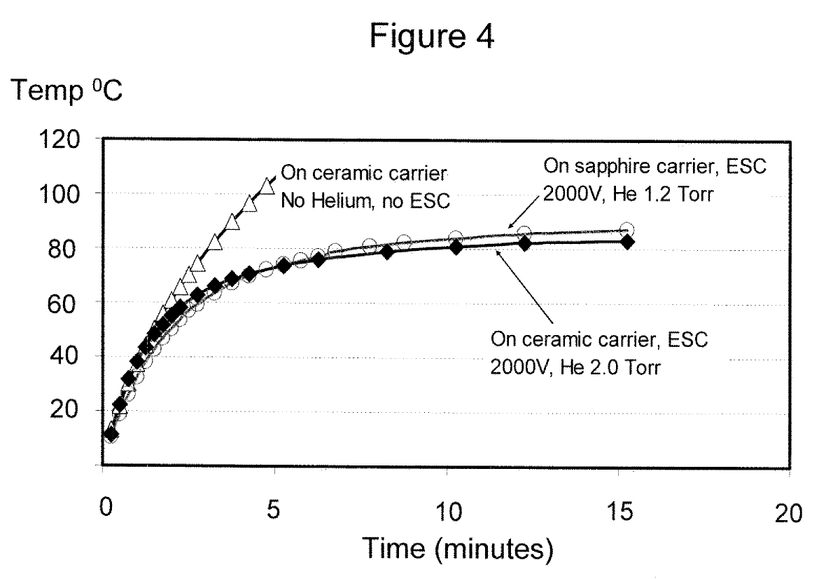

As an example, FIG. 4 illustrates through a graph of temperature versus time the improved cooling efficiency possible using the current invention. The wafer temperature attained when an unclamped carrier was used and hence no helium could be used, exceeds 120° C. in approximately five minutes. This temperature rise results in an un-useable process. The same process parameters, using either a clamped sapphire or clamped alumina ceramic carrier and helium cooling, resulted in a wafer temperature of approximately 85° C. even after fifteen minutes. This temperature rise and stabilization of temperature is low enough to produce good etch results.

As another example, a process was developed to etch a deep trench into silicon on a fragile MEMS device. The power input was limited such that the wafer temperature did not rise to a point where resist degradation occurred. Processing without clamping resulted in a maximum etch rate of less than one micron per minute. By using a wafer carrier and clamping to an ESC, it was possible to maintain a backside helium pressure of 3 Torr which allowed a higher RF power to be used for plasma processing. As a result an etch rate of greater than 1.5 microns per minute could be easily achieved which resulted in a greater than 50% improvement in throughput for this process.

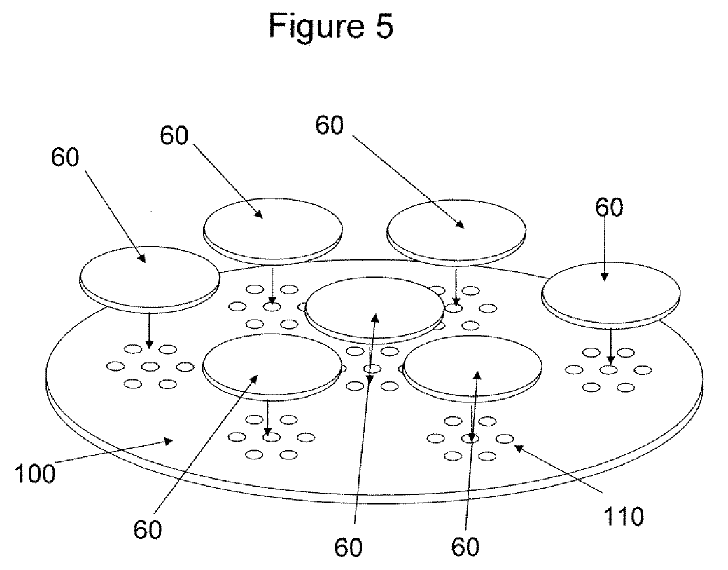

As described, the present invention works for transporting a single thin or fragile wafer. It can also be used effectively for transporting multiple thin or fragile wafers as shown in FIG. 5. For many newly emerging materials, such as SiC and CaN, the available substrate size is limited in many instances to 2 inches or 3 inches in diameter. In order to ensure a wafer throughput rate which permits economical device production, it is necessary to process multiple wafers at a time (batch processing). In order to take advantage of the higher etch rates attained using high density sources such as ICP, it is also necessary to provide wafer cooling for the reasons outlined above. Clamping and cooling multiple substrates in a single batch using a mechanical clamp is difficult to implement successfully and prone to failure. Bonding the substrates to the carrier (using adhesive or adhesive tape) can provide effective cooling. However, the bonding and de-bonding procedure is time consuming and is unsatisfactory when thin or fragile substrates are used due to breakage problems caused by the additional wafer handling. ESC clamping is possible, but the most straightforward approach involves the use of a substrate support which effectively comprises “x” individual ESC's, where x is the number of substrates in the batch. This type of clamping is very costly and also prone to failure. Simplistically, the probability of failure will be proportional to the number of individual ESC's.

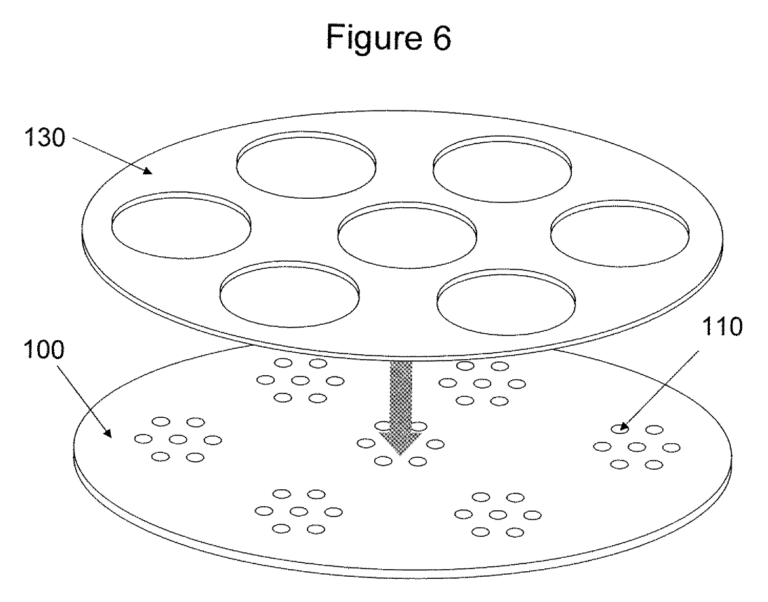

Using the current invention, multiple substrates can be placed on a single thin carrier 100. For example, as shown in FIG. 5, seven two inch substrates 60 can be placed on an eight inch in diameter carrier 100 and the carrier 100 can then be handled as outlined above. The individual substrates 60 are clamped through the carrier 100 material, allowing effective cooling of the substrates 60. A plurality of holes 10 for helium gas can be made in the carrier 100 behind each substrate 60 allowing the gas to permeate this region and improve the cooling of the substrates 60. If necessary, wafer retention pins 120, as shown in FIG. 3, can also be added to the carrier 100. The carrier 100 surface located between the substrates 60 is exposed to the plasma. If this exposure to plasma is deemed undesirable, the surface of the carrier 100 can be protected by a coating or by using a cover piece 130 made from an appropriate material designed to match the substrate 60 locations as shown in FIG. 6. The cover piece 130 can also serve as a wafer retention device. This cover piece 130 may be made from materials such as quartz, silicon carbide or other materials chosen for compatibility with a specific process. This cover piece 130 may constitute a separate interchangeable component, it may be bonded to the wafer carrier 100 or it may be fabricated as an intrinsic part of the wafer carrier 100. Whereas, coating the bottom of the carrier 100 (the side in contact with the electrostatic chuck 20) with a thin layer of conductive material in the regions between the substrate locations can locally increase the clamping force of the substrate to the carrier 100 and thereby improve the helium sealing capability.

The present disclosure includes that contained in the appended claims, as well as that of the foregoing description. Although this invention has been described in its preferred form with a certain degree of particularity, it is understood that the present disclosure of the preferred form has been made only by way of example and that numerous changes in the details of construction and the combination and arrangement of parts may be resorted to without departing from the spirit and scope of the invention.

Now that the invention has been described,

What is claimed is:

1. An apparatus for carrying at least one substrate for plasma processing, comprising:
a substrate support;
a carrier for transporting the substrate onto said substrate support, wherein the substrate is located unbonded on said carrier; and
a clamping mechanism coupled to said substrate support, wherein said clamping mechanism is configured to move between an inactive position and an active position, whereby the substrate is clamped to said substrate support through said carrier when said clamping mechanism is in said active position.

2. The apparatus according to claim 1 wherein said carrier further comprising a cover plate.

3. The apparatus according to claim 1 wherein said carrier further comprising at least one recess, the substrate being position within said recess.

4. The apparatus according to claim 1 wherein said carrier further comprising a plurality of retaining pins, the substrate being position on said carrier by said plurality of retaining pins.

5. The apparatus according to claim 1 wherein said carrier further comprising a plurality of holes, said plurality of holes conducting a gas to the backside of the substrate.

6. An apparatus for carrying at least one substrate for plasma processing, comprising:
a substrate support;
a carrier for transporting the substrate onto said substrate support, wherein the substrate is located unbonded on said carrier; and
an electrostatic clamp coupled to said substrate support, wherein the substrate is electrostatically secured to said substrate support through said carrier by said electrostatic clamp.

7. The apparatus according to claim 6 wherein said carrier further comprises a dielectric material.

8. The apparatus according to claim 7 wherein said dielectric material is selected from the group consisting of alumina, aluminum oxide ceramic, sapphire and quartz.

9. The apparatus according to claim 6 wherein said carrier further comprising a cover plate.

10. The apparatus according to claim 6 wherein said carrier further comprising at least one recess, the substrate being position within said recess.

11. The apparatus according to claim 6 wherein said carrier is a membrane.

12. The apparatus according to claim 6 wherein said carrier further comprising a plurality of retaining pins, the substrate being position on said carrier by said plurality of retaining pins.

13. The apparatus according to claim 6 wherein said carrier further comprising a plurality of holes, said plurality of holes conducting a gas to the backside of the substrate.

14. The apparatus according to claim 6 wherein said carrier further comprising a conductive layer on at least part of the bottom of said carrier.

15. A method for carrying at least one substrate for plasma processing, comprising:
providing a substrate support;
providing an electrostatic clamp coupled to said substrate support;
providing a carrier;
placing the substrate onto said carrier, the substrate is located unbonded on said carrier;
transporting said carrier with the unbonded substrate onto said substrate support; and
electrostatically clamping the substrate to said substrate support through said carrier by said electrostatic clamp.

16. The method according to claim 15 wherein said carrier further comprises a dielectric material.

17. The method according to claim 16 wherein said dielectric material is selected from the group consisting of alumina, aluminum oxide ceramic, sapphire and quartz.

18. The method according to claim 15 wherein the substrate is a MEMS substrate.

19. The method according to claim 15 wherein the substrate is a fragile substrate.

20. The method according to claim 15 wherein the substrate further comprising a dielectric film.

21. The method according to claim 20 wherein said dielectric film is silicon dioxide.

22. The method according to claim 15 wherein the substrate is electrically conducting.

23. The method according to claim 15 wherein the substrate is partially conducting.

24. The method according to claim 23 wherein the substrate is selected from the group consisting of silicon and silicon carbide.

25. The method according to claim 15 wherein said carrier further comprising at least one recess for holding the substrate unbonded in a fixed position on said carrier.

26. The apparatus according to claim 15 wherein said carrier is a membrane.

27. The method according to claim 15 wherein said carrier further comprising a plurality of retaining pins for holding the substrate unbonded in a fixed position on said carrier.

28. The method according to claim 15 wherein said carrier further comprising a conductive layer on at least part of the bottom of said carrier.

29. The method according to claim 15 wherein said carrier further comprising a plurality of holes.

30. The method according to claim 29 further comprising providing a gas to the backside of the substrate through said plurality of holes in said carrier

31. The method according to claim 30 wherein said gas is helium.
